(19) United States
(12) Patent Application Publication
(10) Pub. No.: US 2024/0284761 A1
(43) Pub. Date: Aug. 22, 2024

(54) FOLDABLE DISPLAY DEVICE AND METHOD OF MANUFACTURING THE SAME

(71) Applicant: SAMSUNG DISPLAY CO., LTD., Yongin-si (KR)

(72) Inventors: ONNURI KIM, Yongin-si (KR); YOUNGHYE SON, Yongin-si (KR); SANG-GU LEE, Yongin-si (KR)

(21) Appl. No.: 18/525,788

(22) Filed: Nov. 30, 2023

(30) Foreign Application Priority Data
Feb. 9, 2023 (KR) 10-2023-0017422

(51) Int. Cl. H10K 59/80; H10K 59/12

(52) U.S. Cl. CPC H10K 59/873; H10K 59/1201

(57) ABSTRACT

A display device includes a display panel including a first non-folding area, a second non-folding area, and a folding area disposed between the first non-folding area and the second non-folding area. A buffer is disposed on the display panel and has a thickness decreasing from a central portion thereof toward an edge thereof overlapping the display panel. A cover window is disposed on the buffer.

This application claims priority under 35 U.S.C. § 119 to Korean Patent Application No. 10-2023-0017422, filed on Feb. 9, 2023, the content of which in its entirety is herein incorporated by reference.

### TECHNICAL FIELD

The present disclosure relates to a display device and more specifically, to a foldable display device and a manufacturing method of the foldable display device.

### DISCUSSION OF THE RELATED ART

Recently, a flexible display device that can be deformed into various shapes has been developed. Unlike a conventional flat panel display, a flexible display device can be folded, bent, or rolled like paper. The flexible display device is convenient and easy to carry.

Recently, among flexible display devices, a foldable display device is in the limelight. The foldable display device can be repeatedly folded and unfolded to a noticeable degree without cracking or otherwise sustaining damage. The foldable display may include an impact buffer to increase impact resistance of the foldable display. Such an impact buffer may be provided in a form of a film.

### SUMMARY

A display device, according to an embodiment of the present disclosure, includes a display panel including a first non-folding area, a second non-folding area, and a folding area disposed between the first non-folding area and the second non-folding area. A buffer is disposed on the display panel and has a thickness decreasing from a central portion thereof toward an edge thereof overlapping the display panel. A cover window is disposed on the buffer.

In an embodiment, the buffer may directly contact the display panel.

In an embodiment, the buffer may include a curable resin.

In an embodiment, the buffer may include a urethane acrylate-based resin.

In an embodiment, the buffer may further include 2-propenoic acid, (5-ethyl-1,3-dioxin-5-yl) methyl ester.

In an embodiment, a modulus of the buffer may be in a range of about 65 Mpa to about 150 Mpa.

In an embodiment, a thickness of the central portion of the buffer may be in a range of about 25 micrometers to about 100 micrometers.

In an embodiment, the display panel may include a circuit element layer including at least one transistor, a light emitting element layer including at least one light emitting diode and disposed on the circuit element layer, and an encapsulation layer disposed on the light emitting element layer.

In an embodiment, the buffer may directly contact the encapsulation layer.

In an embodiment, the display panel may further include a functional layer disposed on the encapsulation layer.

In an embodiment, the buffer may directly contact the functional layer.

In an embodiment, the display device may further include an adhesive layer disposed on the buffer, disposed under the cover window, and having a thickness decreasing from a central portion thereof toward an edge thereof overlapping the display panel.

In an embodiment, the adhesive layer may directly contact each of the buffer and the cover window.

In an embodiment, the adhesive layer may include a curable resin.

In an embodiment, a thickness of the central portion of the adhesive layer may be in a range of about 35 micrometers to about 100 micrometers.

In an embodiment, each of the adhesive layer and the buffer may have a viscosity of greater than 0 cP and less than about 50 cP at room temperature.

In an embodiment, the display device may further include an adhesive layer disposed on the display panel, disposed under the buffer, and having a thickness decreasing from a central portion thereof toward an edge thereof overlapping the display panel.

In an embodiment, the adhesive layer may directly contact each of the display panel and the buffer.

In an embodiment, the buffer may directly contact each of the adhesive layer and the cover window.

A method of manufacturing a display device according to an embodiment of the present disclosure includes forming a display panel including a first non-folding area, a second non-folding area, and a folding area disposed between the first non-folding area and the second non-folding area. A buffer having a thickness decreasing from a central portion thereof toward an edge thereof overlapping the display panel is formed on the display panel. A cover window is formed on the buffer.

In an embodiment, the buffer may be formed through an inkjet process.

In an embodiment, the forming the buffer may include forming a first uncured resin layer on the display panel by the inkjet process and curing the first uncured resin layer to form the buffer.

In an embodiment, the buffer may be formed of a urethane acrylate-based resin.

In an embodiment, the buffer may be formed of a resin containing 2-propenoic acid, (5-ethyl-1,3-dioxin-5-yl) methyl ester.

In an embodiment, the method may further include forming an adhesive layer having a thickness decreasing from a central portion thereof toward an edge thereof overlapping the display panel, on the buffer.

In an embodiment, the adhesive layer may be formed by an inkjet process.

In an embodiment, the forming the adhesive layer may include forming a second uncured resin layer on the buffer by the inkjet process and curing the second uncured resin layer to form the adhesive layer.

In an embodiment, the method may further include forming an adhesive layer having a thickness decreasing from a central portion thereof toward an edge thereof overlapping the display panel, on the display panel.

In an embodiment, the forming the adhesive layer may include forming a second uncured resin layer on the display panel by the inkjet process and curing the second uncured resin layer to form the adhesive layer.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a perspective view illustrating an unfolded state of a display device according to an embodiment of the present disclosure;

FIG. 2 is a cross-sectional view illustrating a folded state of the display device of FIG. 1;

FIG. 3 is a cross-sectional view taken along line I-I′ of FIG. 1;

FIG. 4 is a cross-sectional view illustrating a pixel included in the display panel of FIG. 3 according to an embodiment of the present disclosure;

FIG. 5 is a cross-sectional view illustrating an enlarged area A of FIG. 3 according to an embodiment of the present disclosure;

FIG. 6 is a cross-sectional view illustrating a pixel included in the display panel of FIG. 3 according to an embodiment of the present disclosure;

FIG. 7 is a cross-sectional view illustrating a pixel included in the display panel of FIG. 3 according to an embodiment of the present disclosure;

FIG. 8 is a cross-sectional view illustrating an example of FIG. 3;

FIG. 9 is a cross-sectional view illustrating an enlarged area B of FIG. 8 according to an embodiment of the present disclosure;

FIG. 10 is a cross-sectional view illustrating an enlarged area B of FIG. 8 according to an embodiment of the present disclosure;

FIGS. 11 to 17 are cross-sectional views illustrating a manufacturing method of a display device according to an embodiment of the present disclosure; and

FIGS. 18 to 23 are cross-sectional views illustrating a manufacturing method of a display device according to an embodiment of the present disclosure.

### DETAILED DESCRIPTION

The invention will now be described more fully hereinafter with reference to the accompanying drawings, in which various embodiments are shown. This invention may, however, be embodied in many different forms, and should not necessarily be construed as limited to the embodiments set forth herein. Rather, these embodiments are provided so that this disclosure will be thorough and complete, and will fully convey the scope of the invention to those skilled in the art. Like reference numerals may refer to like elements throughout the specification and figures.

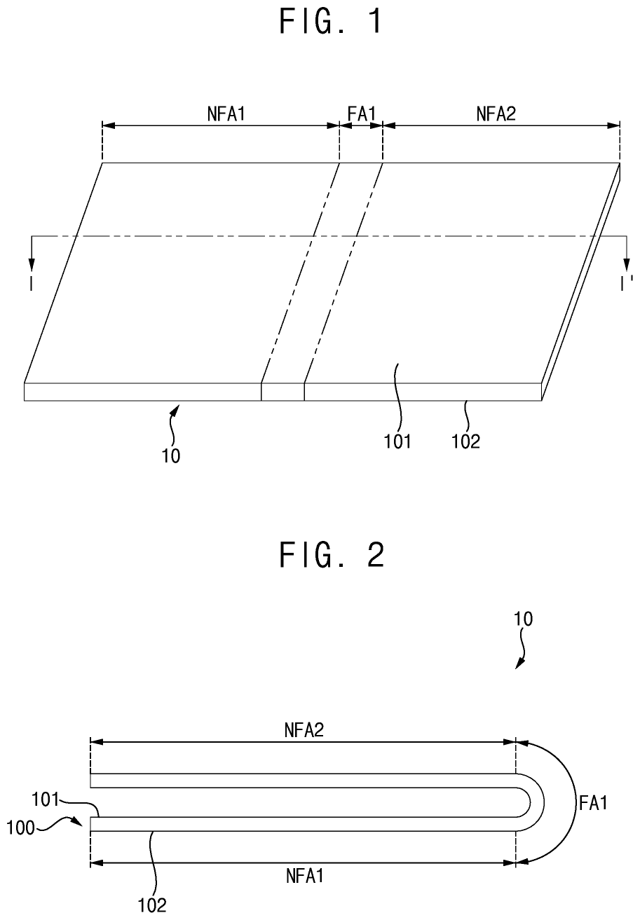

FIG. 1 is a perspective view illustrating an unfolded state of a display device according to an embodiment. FIG. 2 is a cross-sectional view illustrating a folded state of the display device of FIG. 1.

Referring to FIGS. 1 and 2, the display device 10 may include a display surface 101 and a non-display surface 102 opposite to the display surface 101. The display surface 101 may be a surface on which an image is displayed on the display device 10. The non-display surface 102 may be a surface on which an image is not displayed on the display device 10. In an embodiment, the image may also be displayed on the non-display surface 102. For example, the image may be displayed on a portion of the non-display surface 102. Alternatively, the image may be displayed on the non-display surface 102 entirely.

The display device 10 may have a stacked structure. For example, the display device 10 may include several layers having different functions all stacked upon each other. Each of the various layers may be flexible, and thus the display device 10 may be flexible.

The display device 10 may include a first non-folding area NFA1, a second non-folding area NFA2, and a folding area FA disposed between the first non-folding area NFA1 and the second non-folding area NFA2.

The display device 10 might not be folded in the first and second non-folding areas NFA1 and NFA2. The display device 10 may have a flat surface in the first and second non-folding areas NFA1 and NFA2.

The display device 10 may be folded and unfolded in the folding area FA. The display device 10 may be folded (e.g., a folded state in FIG. 2) or unfolded (e.g., an unfolded state in FIG. 1) in the folding area FA. Also, the display device 10 may be in-folded or out-folded. For example, the display surface 101 of the display device 10 may be in-folded to face each other. However, in an embodiment, the non-display surface 102 of the display device 10 may be out-folded to face each other.

However, embodiments according to the present invention are not necessarily limited thereto, and in an embodiment, the display device 10 may further include a third non-folding part adjacent to the second non-folding area NFA2. In addition, the display device 10 may further include a folding area disposed between the second non-folding area NFA2 and the third non-folding part. Also, in an embodiment, a width of the folding area FA may be relatively large. Therefore, the display device 10 may slide in the folding area FA, and thus an area of the display surface 101 may be adjusted.

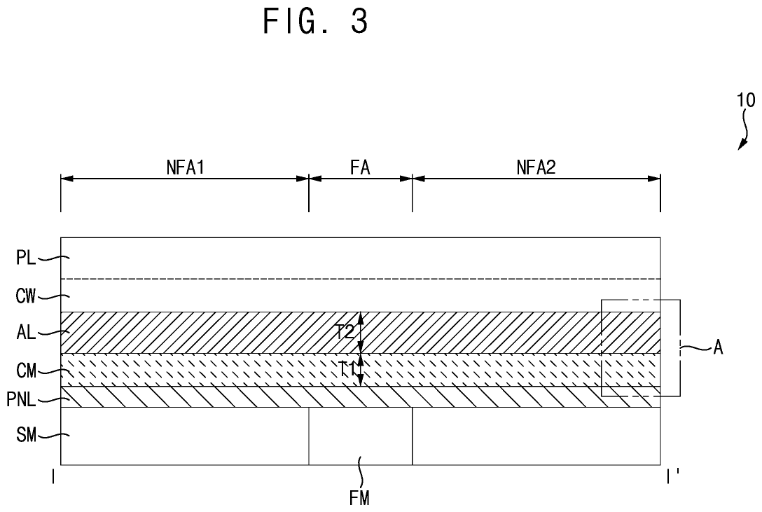

FIG. 3 is a cross-sectional view taken along line I-I′ of FIG. 1.

Referring to FIG. 3, the display device 10 may include a support SM, a filling FM, a display panel PNL, a buffer CM, an adhesive layer AL, a cover window CW, and a protective film PL. As described above, since the display device 10 can be folded or unfolded, the support SM, the filling FM, the display panel PNL, the buffer CM, the adhesive layer AL, the cover window CW and the protective film PL may be flexible.

The support SM may support the display panel PNL and may emit or disperse heat generated from the display panel PNL. Also, the support SM may prevent foreign matter from being introduced into the display panel PNL from outside the display device.

An opening OP overlapping the folding area FA may be defined in the support SM. The filling FM may overlap the folding area FA and fill the opening OP. However, the present invention is not necessarily limited thereto.

The display panel PNL may be disposed on the support SM. The display panel PNL may include a plurality of pixels, and the image may be generated by combining light emitted from each of the pixels.

In an embodiment, the buffer CM may be disposed on the display panel PNL. The buffer CM may directly contact the display panel PNL and may be attached on the display panel PNL.

In an embodiment, the adhesive layer AL may be disposed on the buffer CM. The adhesive layer AL may directly contact each of the buffer CM and the cover window CW. For example, the adhesive layer AL may bond the buffer CM and the cover window CW.

The cover window CW may be disposed on the adhesive layer AL. The cover window CW may protect the display panel PNL. The cover window CW may be formed of a transparent material. The cover window CW may be bonded to the display panel PNL through the adhesive layer AL.

For example, the cover window CW may include ultra-thin tempered glass. The ultra-thin tempered glass may be strengthened to have a predetermined stress profile. The ultra-thin tempered glass, which has been strengthened, may be more resistant to crack generation, propagation of cracks, damage, or the like due to external impact than before tempering. The ultra-thin tempered glass strengthened through a strengthening process may have various stresses for each region.

When the glass is formed of an ultra-thin film or a thin film, the glass may be flexible and may have a property that can be bent, folded, or rolled. The ultra-thin tempered glass of the cover window CW may be thin glass that is chemically strengthened to have high strength. However, the present invention is not necessarily limited thereto, and the ultra-thin tempered glass of the cover window CW may be a thermally strengthened thin film glass.

The protective film PL may be disposed on the cover window CW. The protective film PL may perform scattering of the cover window CW, shock absorption, stamping prevention, fingerprint prevention, and/or glare prevention. The protective film PL may include a transparent polymer film. The transparent polymer film may include epoxy resin, polyurethane, polyester, polyethylene terephthalate, polyethylene naphthalate, polyimide, polyarylate, polycarbonate, polymethyl methacrylate, ethyl vinyl acetate, polyamide resin, and/or the like.

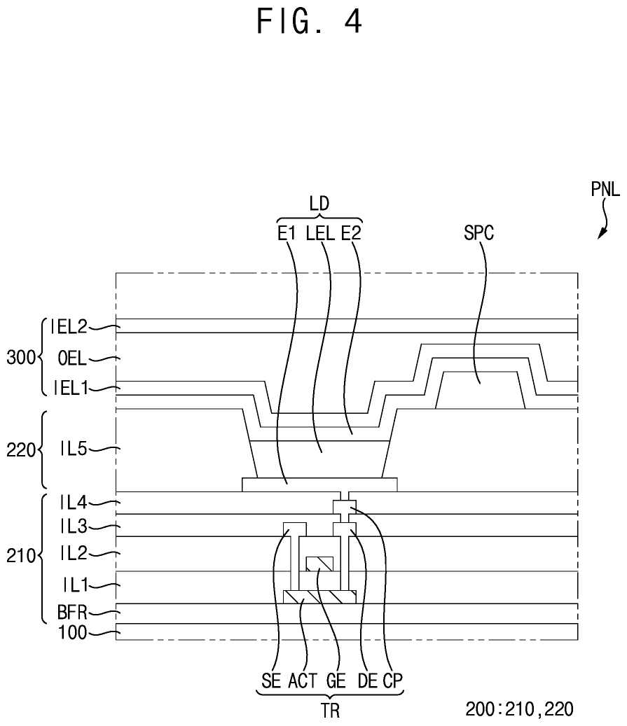

FIG. 4 is a cross-sectional view illustrating a pixel included in the display panel of FIG. 3 according to an embodiment.

Referring to FIG. 4, the display panel PNL may include a substrate SUB, a display element layer 200, and an encapsulation layer 300. The display element layer 200 may include a circuit element layer 210 and a light emitting element layer 220.

The circuit element layer 210 may be disposed on the substrate SUB, and include a buffer layer BFR, at least one transistor TR, a connection electrode CP, a first insulating layer IL1, a second insulating layer IL2, a third insulating layer IL3, and a fourth insulating layer IL4. The transistor TR may include an active layer ACT, a gate electrode GE, a source electrode SE, and a drain electrode DE. The light emitting element layer 220 may be disposed on the circuit element layer 210 and include a fifth insulating layer IL5, a spacer SPC, and at least one light emitting diode LD. The light emitting diode LD may include a first electrode E1, a light emitting layer LEL, and a second electrode E2.

The substrate SUB may be an insulating substrate formed of a transparent material. The substrate SUB may include glass and/or plastic.

The buffer layer BFR may be disposed on the substrate SUB. The buffer layer BFR may prevent diffusion of metal atoms or impurities from the substrate SUB into the active layer ACT.

The active layer ACT may be disposed on the buffer layer BFR. The active layer ACT may be divided into a source region and a drain region doped with impurities and a channel region between the source region and the drain region.

The first insulating layer IL1 may be disposed on the buffer layer BFR. The first insulating layer IL1 may cover the active layer ACT and may have substantially a same thickness along a profile of the active layer ACT. However, the present invention is not necessarily limited thereto. For example, the first insulating layer IL1 may include an inorganic material.

The gate electrode GE may be disposed on the first insulating layer IL1. In an embodiment, the gate electrode GE may overlap the channel region of the active layer ACT.

The second insulating layer IL2 may be disposed on the first insulating layer IL1. In addition, the second insulating layer IL2 may cover the gate electrode GE and may be disposed with substantially a same thickness along a profile of the gate electrode GE. However, the present invention is not necessarily limited thereto. For example, the second insulating layer IL2 may include an inorganic material.

The source electrode SE and the drain electrode DE may be disposed on the second insulating layer IL2. The source electrode SE may contact the source region of the active layer ACT through a first contact hole formed in the first and second insulating layers IL1 and IL2. The drain electrode DE may contact the drain region of the active layer ACT through a second contact hole formed in the first and second insulating layers IL1 and IL2.

The third insulating layer IL3 may be disposed on the second insulating layer IL2. In addition, the third insulating layer IL3 may cover the source and drain electrodes SE and DE, and have a substantially flat upper surface without creating a step around the source and drain electrodes SE and DE. For example, the third insulating layer IL3 may include an organic material.

The connection electrode CP may be disposed on the third insulating layer IL3. The connection electrode CP may contact the source electrode SE or the drain electrode DE through a third contact hole formed in the third insulating layer IL3.

The fourth insulating layer IL4 may be disposed on the third insulating layer IL3. In addition, the fourth insulating layer IL4 may cover the connection electrode CP and may have a substantially flat upper surface without creating a step around the source and drain electrodes SE and DE. For example, the fourth insulating layer IL4 may include an organic material.

The first electrode E1 may be disposed on the fourth insulating layer IL4. The first electrode E1 may have reflective or light-transmitting properties. For example, the first electrode E1 may include metal.

The first electrode E1 may contact the connection electrode CP through a fourth contact hole formed in the fourth insulating layer IL4. Through this, the first electrode E1 may be connected to the transistor TR.

The fifth insulating layer IL5 may be disposed on the fourth insulating layer IL4, and an opening exposing an upper surface of the first electrode E1 may be defined in the fifth insulating layer IL5. For example, the fifth insulating layer IL5 may include an organic material or an inorganic material.

The spacer SPC may be disposed on the fifth insulating layer IL5. For example, the spacer SPC may include an organic material or an inorganic material. The spacer SPC may maintain a gap between the encapsulation layer 300 and the substrate SUB.

The spacer SPC may include a material that is different from a material of the fifth insulating layer IL5. The spacer SPC may be formed after the fifth insulating layer IL5 is formed. However, embodiments according to the present invention are not necessarily limited thereto, and the spacer SPC may include a same material as a material of the fifth insulating layer IL5. For example, the fifth insulating layer IL5 and the spacer SPC may include an organic material such as polyimide. Also, the fifth insulating layer IL5 and the spacer SPC may be simultaneously formed using a halftone mask.

The light emitting layer LEL may be disposed on the first electrode E1. The light emitting layer LEL may be disposed in the opening formed in the fifth insulating layer IL5. In an embodiment, the light emitting layer LEL may have a multilayer structure including a hole injection layer, a hole transport layer, an organic light emitting layer, an electron transport layer, and an electron injection layer. The organic light emitting layer may include a light emitting material.

The second electrode E2 may cover the light emitting layer LEL and may be disposed on the fifth insulating layer IL5 and the spacer SPC. In an embodiment, the second electrode E2 may have a plate shape. In addition, the second electrode E2 may have light transmitting or reflecting properties. For example, the second electrode E2 may include metal.

The encapsulation layer 300 may be disposed on the light emitting element layer 220. The encapsulation layer 300 may prevent moisture and oxygen from penetrating into the light emitting diode LD from the outside the display device. For example, the encapsulation layer 300 may include a first inorganic encapsulation layer IEL1, an organic encapsulation layer OEL, and a second inorganic encapsulation layer IEL2.

The first inorganic encapsulation layer IEL1 may be disposed on the second electrode E2 with substantially a same thickness along a profile of the second electrode E2. The organic encapsulation layer OEL may be disposed on the first inorganic encapsulation layer IEL1, and may have a substantially flat upper surface without creating a step around the first inorganic encapsulation layer IEL1. The second inorganic encapsulation layer IEL2 may be disposed on the organic encapsulation layer OEL.

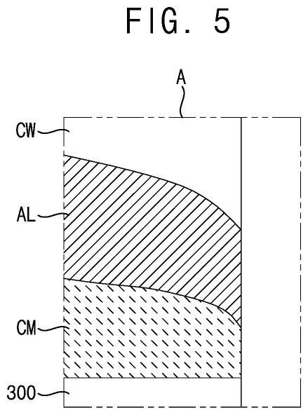

FIG. 5 is a cross-sectional view illustrating an enlarged area A of FIG. 3 according to an embodiment.

Referring to FIGS. 3 to 5, in an embodiment, the buffer CM may be disposed on the display panel PNL. For example, the buffer CM may directly contact the encapsulation layer 300 on the encapsulation layer 300.

A thickness of the buffer CM may decrease from a central portion thereof toward an edge of a portion of an edge overlapping the display panel PNL. For example, a thickness of the central portion of the buffer CM and a thickness of the edge of the buffer CM may be different from each other, and the thickness of the buffer CM may gradually decrease toward the edge of the buffer CM.

In an embodiment, the buffer CM may be formed by an inkjet process. The buffer CM may include a curable resin. For example, the buffer CM may include a urethane acrylate-based resin. In addition, the buffer CM may further include 2-propenoic acid, (5-ethyl-1,3-dioxin-5-yl) methyl ester. For example, the buffer CM may include a compound represented by Chemical Formula 1 below.

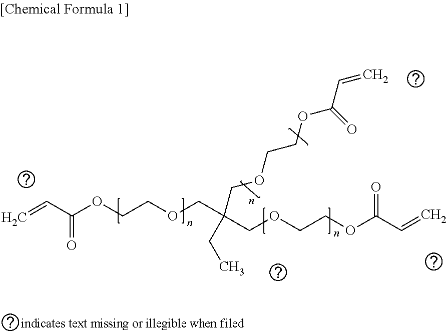

In an embodiment, a modulus of the buffer CM may be in a range of about 65 Mpa to about 150 Mpa. When the modulus of the buffer CM is smaller than about 65 Mpa, the buffer CM might not absorb an external shock and may transmit a shock to the display panel PNL. When the modulus of the buffer CM is greater than about 150 Mpa, the cover window CW and the display panel PNL may also be damaged because the buffer CM is broken or damaged by an external impact.

In addition, Table 1 below shows a pen drop evaluation (crack height of the cover window) according to the modulus of the buffer CM. The crack height of the cover window may mean a minimum height at which the cover window is damaged by the pen. Experimental structures according to Example 1, Comparative Example 1, and Comparative Example 2 are formed in a form of a buffer having a modulus according to Table 1 below, a cover window disposed on the buffer, and a protective film disposed on the cover window.

TABLE 1

| | | Comparative | Comparative |
|---|---|---|---|
| | Example 1 | Example 1 | Example 2 |
| modulus of buffer (MPa) | 150 | 300 | 600 |
| crack height of cover window | 13 | 8 | 10 |
| (cm) | | | |

Referring to Table 1 above, in Example 1, when the modulus of the buffer was about 150 MPa, the crack height of the cover window was about 13 cm. In Comparative Example 1, when the modulus of the buffer was about 300 MPa greater than 150 MPa, the crack height of the cover window was about 8 cm. In Comparative Example 2, when the modulus of the buffer was about 600 MPa greater than 150 MPa, the crack height of the cover window was about 10 cm. Through this, it can be confirmed that when the modulus of the buffer is about 150 MPa or less, the crack height of the cover window increases. For example, when the modulus of the buffer is about 150 MPa or less, it can be confirmed that the impact resistance of the structure including the buffer is increased.

The thickness of the central portion of the buffer CM may be in a range of about 25 micrometers to about 100 micrometers. When the thickness T1 of the central portion of the buffer CM is less than about 25 micrometers, the buffer CM might not sufficiently absorb an external shock, and thus the impact resistance of the display device 10 may deteriorate. When the thickness T1 of the central portion of the buffer CM is greater than about 100 micrometers, the thickness of the display device 10 may increase due to the buffer CM. Also, when the thickness T1 of the central portion of the buffer CM is greater than about 100 micrometers, it might not be easy to fold the display device 10 due to the buffer CM.

A viscosity of the buffer CM may be greater than 0 cP and less than or equal to about 50 cP at room temperature (e.g., about 25° C.). When the viscosity of the buffer CM is greater than about 50 cP, it might not be easy to form the buffer CM by an inkjet process.

In an embodiment, a thickness of the adhesive layer AL may decrease from a central portion thereof toward an edge of a portion of an edge overlapping the display panel PNL. For example, a thickness of the central portion of the adhesive layer AL and a thickness of the edge of the adhesive layer AL may be different from each other, and the thickness of the adhesive layer AL may gradually decrease toward the edge of the adhesive layer AL.

In an embodiment, the adhesive layer AL may include a curable resin. For example, the adhesive layer AL may include an acrylate-based polymer material. However, the present invention is not necessarily limited thereto. Therefore, the adhesive layer AL may be formed by an inkjet process.

Also, the thickness T2 of the central portion of the adhesive layer AL may be in a range of about 35 micrometers to about 100 micrometers. When the thickness T2 of the central portion of the adhesive layer AL is smaller than about 35 micrometers, bonding strength between the cover window CW and the buffer CM may decrease. In addition, since the adhesive layer AL also has impact resistance, the adhesive layer AL does not sufficiently absorb an external shock, and thus the impact resistance of the display device 10 may be deteriorated. When the thickness T2 of the central portion of the adhesive layer AL is greater than about 100 micrometers, the thickness of the display device 10 may increase due to the adhesive layer AL. Also, when the thickness T2 of the central portion of the adhesive layer AL is greater than about 100 micrometers, folding of the display device 10 might not be easy due to the adhesive layer AL.

A viscosity of the adhesive layer AL may be greater than 0 cP and less than or equal to about 50 cP at room temperature (e.g., about 25° C.). When the viscosity of the adhesive layer AL is greater than about 50 cP, it might not be easy to form the adhesive layer AL by an inkjet process.

In an embodiment, since the display device 10 includes the buffer CM and the adhesive layer AL formed of a curable resin on the display panel PNL, material costs may be reduced during the process of manufacturing the display device 10. Thus, productivity of the display device 10 may be increased. In addition, since the display device 10 includes the buffer CM and the adhesive layer AL, impact resistance of the display device 10 may be increased from an external shock such as a pen drop.

Also, since the display device 10 includes only the buffer CM and the adhesive layer AL, a thickness of the display device 10 may be reduced. Accordingly, when the display device 10 is folded, folding stress of the display device 10 may be alleviated.

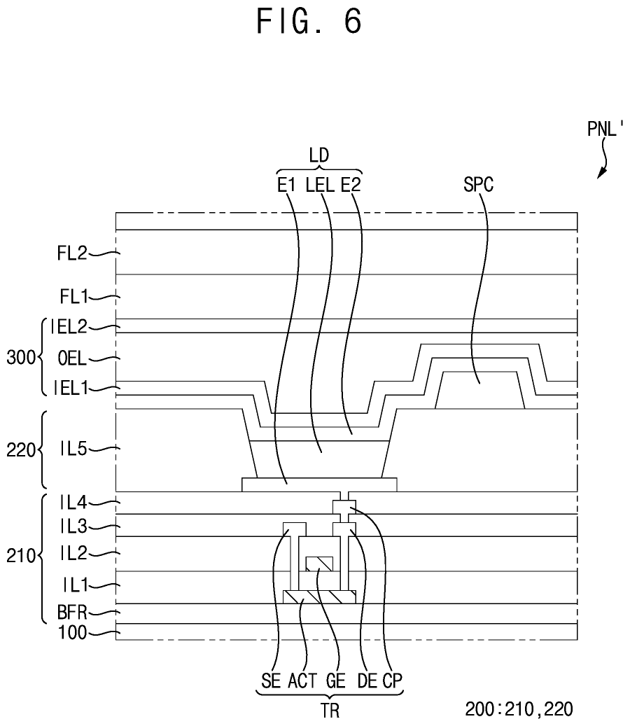

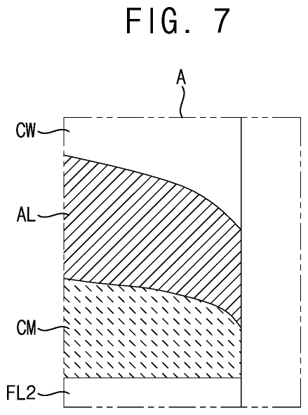

FIG. 6 is a cross-sectional view illustrating a pixel included in the display panel of FIG. 3 according to an embodiment. FIG. 7 is a cross-sectional view illustrating a pixel included in the display panel of FIG. 3 according to an embodiment.

For example, the display panel PNL′ described with reference to FIGS. 6 and 7 may be substantially same as the display panel PNL described with reference to FIGS. 4 and 5, except for a first functional layer FL1 and a second functional layer FL2. Accordingly, to the extent that an element has not been descried in detail with reference to this figure, it may be assumed that the element is at least similar to a corresponding element that has been described elsewhere within the present disclosure. FIG. 7 may be an enlarged cross-sectional view of area A when FIG. 3 includes the display panel of FIG. 6.

Referring to FIG. 6, the display panel PNL′ may include the substrate SUB, the display element layer 200, the encapsulation layer 300, and a functional layer. The display element layer 200 may include the circuit element layer 210 and the light emitting element layer 220. The functional layer may include the first functional layer FL1 and the second functional layer FL2.

The circuit element layer 210 may be disposed on the substrate SUB. The light emitting element layer 220 may be disposed on the circuit element layer 210. The encapsulation layer 300 may be disposed on the light emitting element layer 220. The functional layer may be disposed on the encapsulation layer 300.

For example, the first functional layer FL1 may be disposed on the encapsulation layer 300. For example, the first functional layer FL1 may be a touch sensing layer. The first functional layer FL1 may directly contact the encapsulation layer 300. However, the present invention is not necessarily limited thereto, and the first functional layer FL1 may be attached to the encapsulation layer 300 through an adhesive layer.

The second functional layer FL2 may be disposed on the first functional layer FL1. The second functional layer FL2 may be an anti-reflection layer. For example, the second functional layer FL2 may include a polarizer. When the second functional layer FL2 includes the polarizer, the second functional layer FL2 may be attached to the first functional layer FL1 through an adhesive layer. For example, the second functional layer FL2 may include a color filter layer. When the second functional layer FL2 includes the color filter layer, the second functional layer FL2 may directly contact the first functional layer FL1. However, the present invention is not necessarily limited thereto.

The present invention is not necessarily limited thereto, and the display device 10 may include only one of the first functional layer FL1 and the second functional layer FL2. Further referring to FIG. 7, in an embodiment, the buffer CM may be disposed on the display panel PNL′. For example, the buffer CM may directly contact the second functional layer FL2 on the second functional layer FL2. However, the present invention is not necessarily limited thereto, and when the display device 10 includes only the first functional layer FL1, the buffer CM may directly contact the first functional layer FL1 on the first functional layer FL1.

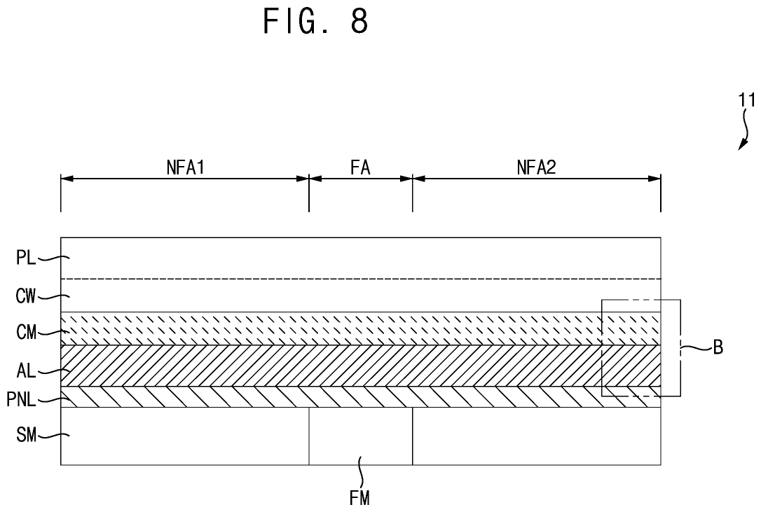

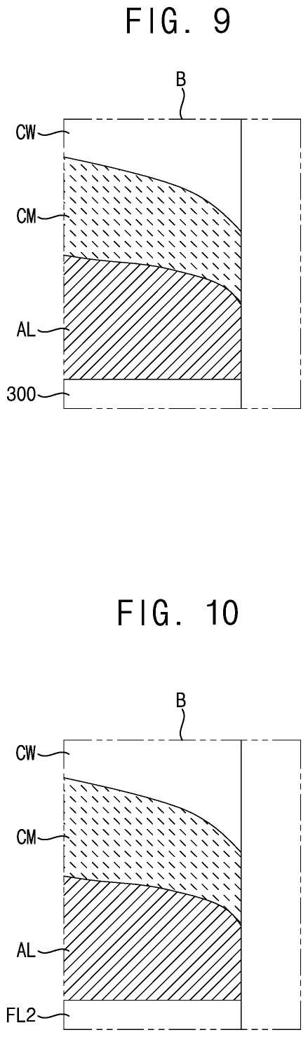

FIG. 8 is a cross-sectional view illustrating an example of FIG. 3. FIG. 9 is a cross-sectional view illustrating an enlarged area B of FIG. 8 according to an embodiment.

The display device 11 described with reference to FIGS. 8 and 9 may be substantially same as the display device 10 described with reference to FIGS. 3 to 5 except for a stacking order of the adhesive layer AL and the buffer CM. Accordingly, to the extent that an element has not been descried in detail with reference to this figure, it may be assumed that the element is at least similar to a corresponding element that has been described elsewhere within the present disclosure.

Referring to FIGS. 8 and 9, a display device 11 may include the support SM, the filling FM, the display panel PNL, the adhesive layer AL, the buffer CM, the cover window CW, and the protective film PL.

In an embodiment, the adhesive layer AL may be disposed on the display panel PNL. The adhesive layer AL may contact the display panel PNL on the display panel PNL. For example, the adhesive layer AL may contact the encapsulation layer 300 included in the display panel PNL.

The buffer CM may be disposed on the adhesive layer AL. The buffer CM may be disposed between the adhesive layer AL and the cover window CW. The buffer CM may directly contact each of the adhesive layer AL and the cover window CW.

The thickness of the buffer CM may decrease from a central portion thereof toward an edge of a portion of an edge overlapping the display panel PNL. Also, the thickness of the buffer CM may decrease from the central portion to the edge of a portion of the edge overlapping the display panel PNL.

FIG. 10 is a cross-sectional view illustrating an enlarged area B of FIG. 8 according to an embodiment.

A display device described with reference to FIG. 10 may be substantially same as the display device 11 described with reference to FIG. 9 except for the display panel PNL′. Accordingly, to the extent that an element has not been descried in detail with reference to this figure, it may be assumed that the element is at least similar to a corresponding element that has been described elsewhere within the present disclosure.

Referring to FIGS. 8 and 10, in an embodiment, the adhesive layer AL may be disposed on the display panel PNL′. The adhesive layer AL may contact the display panel PNL′ on the display panel PNL′. For example, the adhesive layer AL may contact the second functional layer FL2 included in the display panel PNL′ (see FIG. 6). However, the present invention is not necessarily limited thereto, and when the display device 10 includes only the first functional layer FL1, the buffer CM may directly contact the first functional layer FL1 on the first functional layer FL1.

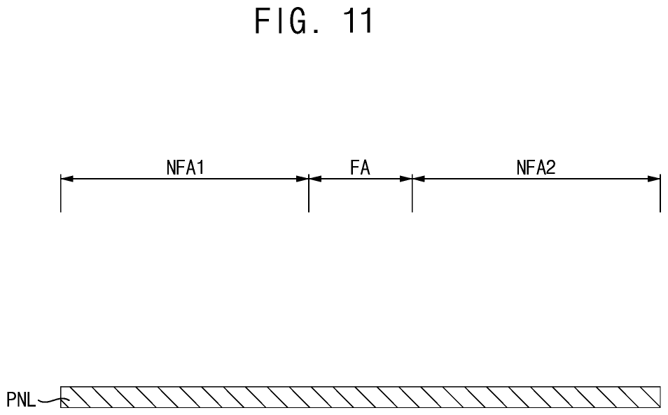

FIGS. 11 to 17 are views illustrating a manufacturing method of a display device according to an embodiment.

For example, the manufacturing method of the display device described with reference to FIGS. 11 to 17 may be a manufacturing method of the display device 10 described with reference to FIGS. 3 to 5.

Referring to FIG. 11, the display panel PNL including the first non-folding area NFA1, the second non-folding area NFA2, and the folding area FA may be formed. For example, the circuit element layer may be formed on the substrate, the light emitting element layer may be formed on the circuit element layer, and the encapsulation layer may be formed on the light emitting element layer (see FIG. 4). However, the present invention is not necessarily limited thereto, and for example, the first functional layer may be further formed on the encapsulation layer, and the second functional layer may be additionally formed on the first functional layer (see FIG. 6).

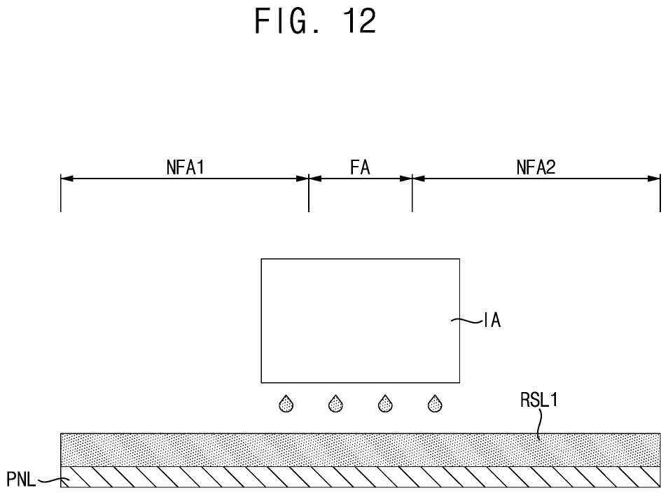

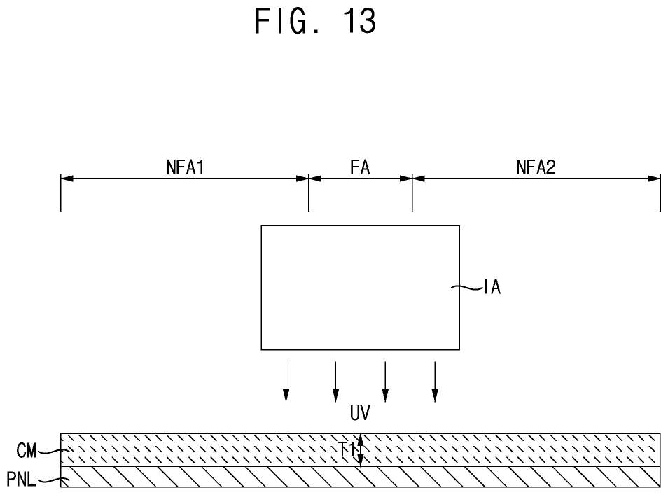

Further referring to FIGS. 12 and 13, the buffer CM may be formed on the display panel PNL. The buffer CM may be formed through an inkjet process.

Referring to FIG. 12, a first uncured resin layer RSL1 may be formed on the display panel PNL by an inkjet process. The inkjet process may be performed by an inkjet apparatus IA, and the inkjet apparatus IA may apply the first uncured resin layer RSL1 on the display panel PNL.

In an embodiment, the first uncured resin layer RSL1 may be formed of a curable resin. For example, the first uncured resin layer RSL1 may be formed of a urethane acrylate-based resin. In addition, the first uncured resin layer RSL1 may be formed of a resin containing 2-propenoic acid, (5-ethyl-1,3-dioxin-5-yl) methyl ester. For example, the first uncured resin layer RSL1 may be formed of a compound represented by Chemical Formula 1 below.

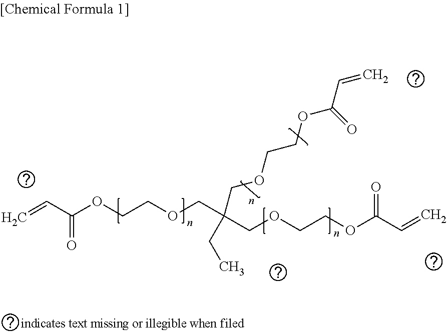

Referring to FIG. 13, the first uncured resin layer RSL1 may be cured to form the buffer CM. The inkjet apparatus IA may radiate ultraviolet light to the first uncured resin layer RSL1 to cure the first uncured resin layer RSL1. However, the present invention is not necessarily limited thereto.

In this case, the thickness T1 of the central portion of the buffer CM may be formed in a range of about 25 micrometers to about 100 micrometers. When the thickness T1 of the central portion of the buffer CM is in a range of about 25 micrometers to about 100 micrometers, the buffer CM sufficiently absorbs an external shock to increase the impact resistance of the display device. Folding of the display device may also be facilitated.

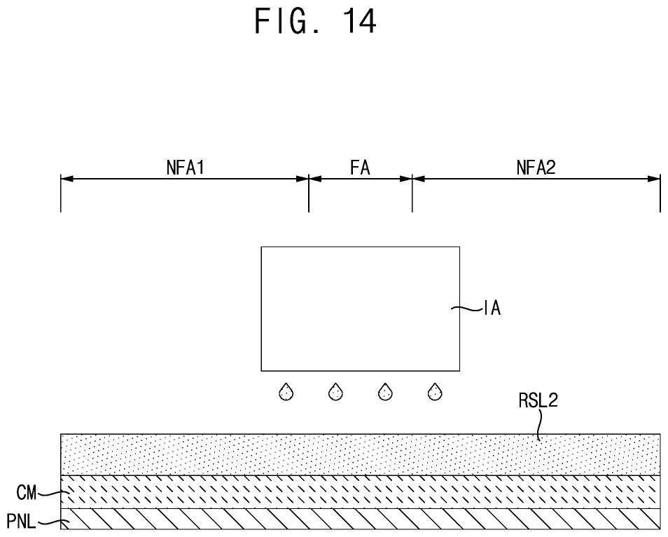

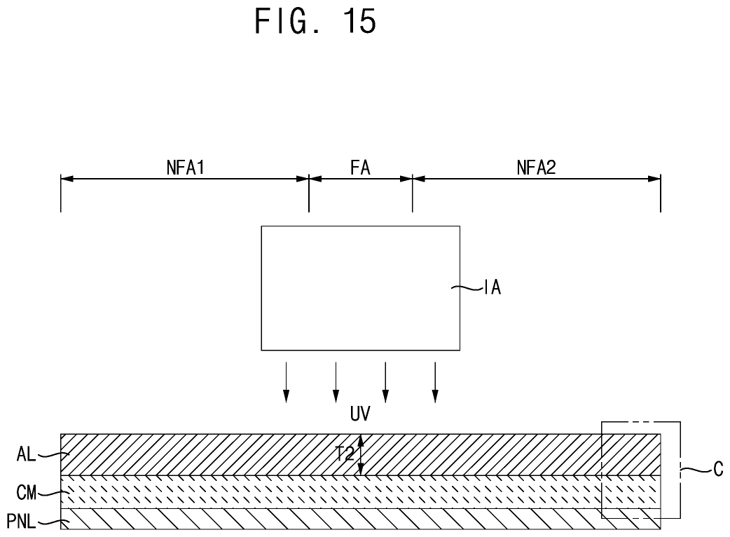

Further referring to FIGS. 14 and 15, the adhesive layer AL may be formed on the buffer CM. The adhesive layer AL may be formed by an inkjet process.

Referring to FIG. 14, a second uncured resin layer RSL2 may be formed on the buffer CM by the inkjet process. The inkjet process may be performed by an inkjet apparatus IA, and the inkjet apparatus IA may apply the second uncured resin layer RSL2 on the display panel PNL. The second uncured resin layer RSL2 may be formed of a curable resin. For example, the second uncured resin layer RSL2 may be formed of an acrylate-based polymer material. However, the present invention is not necessarily limited thereto. The inkjet apparatus IA forming the second uncured resin layer RSL2 may be same as the inkjet apparatus IA forming the first uncured resin layer RSL1. However, the present invention is not necessarily limited thereto, and the inkjet apparatus IA forming the second uncured resin layer RSL2 may be different from the inkjet apparatus IA forming the first uncured resin layer RSL1.

Referring to FIG. 15, the second uncured resin layer RSL2 may be cured to form the adhesive layer AL. The inkjet apparatus IA may radiate ultraviolet light to the second uncured resin layer RSL2 to cure the second uncured resin layer RSL2. However, the present invention is not limited thereto.

The thickness T2 of the central portion of the adhesive layer AL may be formed in a range of about 35 micrometers to about 100 micrometers. When the thickness T2 of the central portion of the adhesive layer AL is in a range of about 35 micrometers to about 100 micrometers, the adhesive layer AL may better bond the cover window CW and the buffer CM, and sufficiently absorb an external impact together with the buffer CM to increase impact resistance of the display device. In addition, folding of the display device may be facilitated.

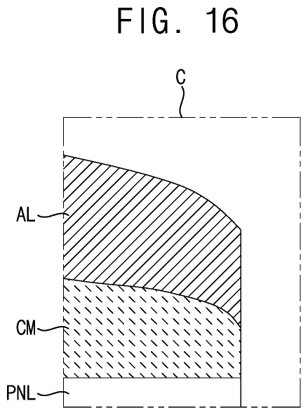

Further referring to FIG. 16, the buffer CM may be formed such that a thickness decreases from the central portion thereof toward the edge at a portion of the edge overlapping the display panel PNL. For example, the buffer CM may be formed by an inkjet process and gradually decrease in thickness toward the edge of the buffer CM.

Also, the adhesive layer AL may be formed such that a thickness decreases from the central portion thereof toward the edge at a portion of the edge overlapping the display panel PNL. For example, the adhesive layer AL may be formed by an inkjet process and gradually decrease in thickness toward the edge of adhesive layer AL.

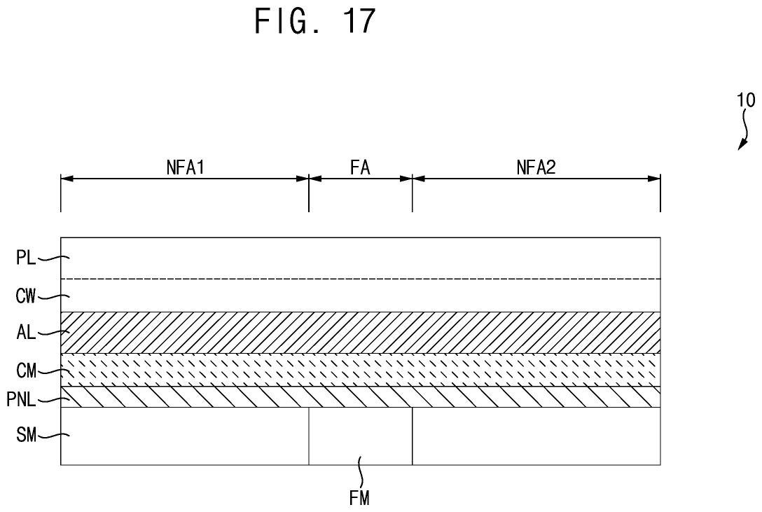

Further referring to FIG. 17, the cover window CW and the protective film PL may be formed on the adhesive layer AL. The cover window CW and the protective film PL may be bonded to the buffer CM through the adhesive layer AL.

Also, the support SM may be formed under the display panel PNL. The opening OP overlapping the folding area FA may be formed in the support SM. The filling FM may be filled in the opening OP. Thus, the display device 10 may be formed.

In an embodiment, since each of the buffer CM and the adhesive layer AL is formed through an inkjet process, material costs may be reduced during the manufacturing process of the display device 10. Accordingly, productivity of the display device 10 may be increased.

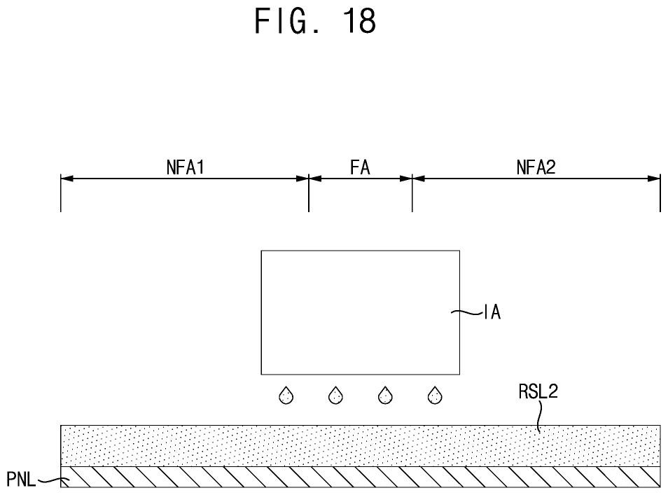

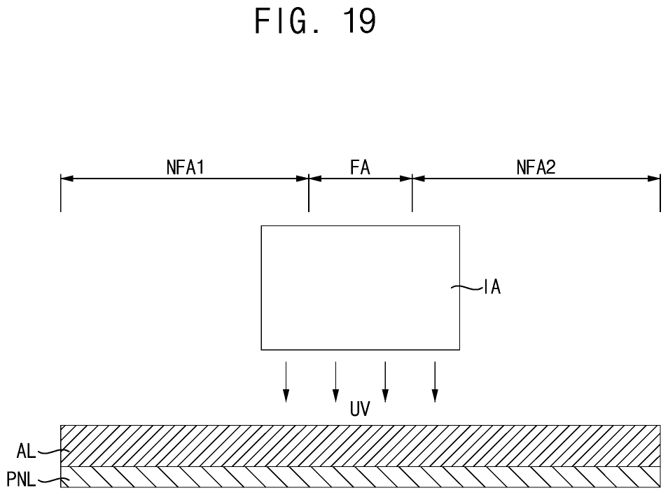

FIGS. 18 to 23 are views illustrating a manufacturing method of a display device according to an embodiment.

For example, the method of manufacturing the display device according to FIGS. 18 to 23 may be a method of manufacturing the display device 11 described with reference to FIGS. 8 and 9. Also, the method of manufacturing the display device according to FIGS. 18 to 23 may be substantially same as the manufacturing method of the display device described with reference to FIGS. 11 to 17 except for an order of manufacturing the adhesive layer AL and the buffer CM. Accordingly, to the extent that an element has not been descried in detail with reference to this figure, it may be assumed that the element is at least similar to a corresponding element that has been described elsewhere within the present disclosure

Referring to FIGS. 18 and 19, the adhesive layer AL may be formed on the display panel PNL. The adhesive layer AL may be formed by an inkjet process.

Referring to FIG. 18, the second uncured resin layer RSL2 may be formed on the display panel PNL by the inkjet process. The inkjet apparatus IA may apply the second uncured resin layer RSL2 on the display panel PNL. The second uncured resin layer RSL2 may be formed of a curable resin.

Referring to FIG. 19, the second uncured resin layer RSL2 may be cured to form the adhesive layer AL. The inkjet apparatus IA may radiate ultraviolet light to the second uncured resin layer RSL2 to cure the second uncured resin layer RSL2.

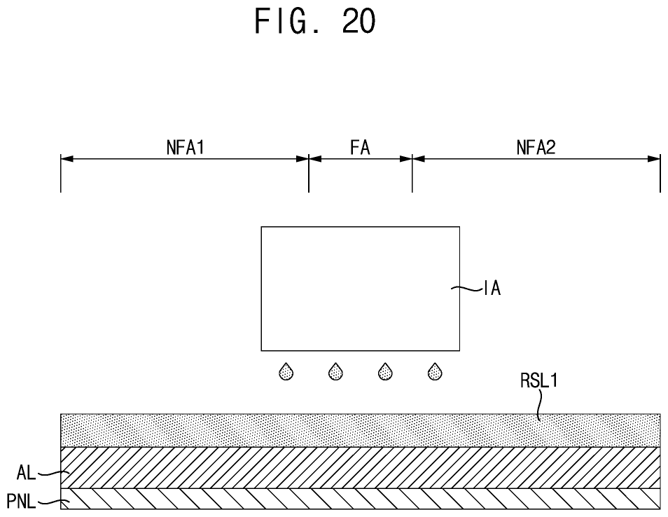

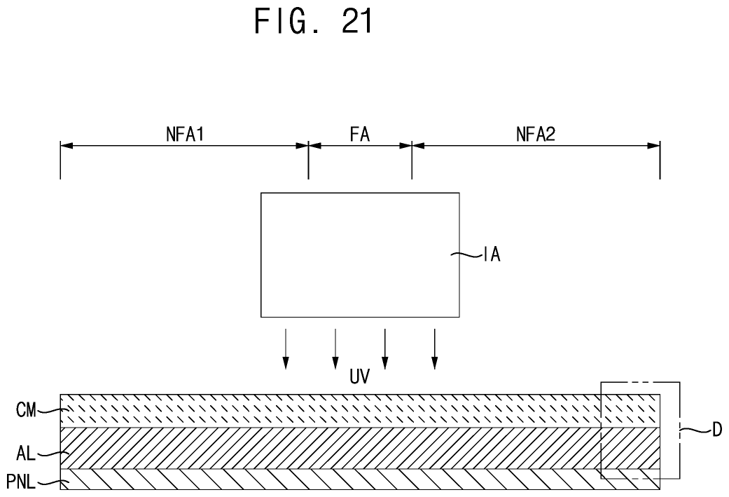

Further referring to FIGS. 20 and 21, the buffer CM may be formed on the adhesive layer AL. The buffer CM may be formed through an inkjet process.

Referring to FIG. 20, the first uncured resin layer RSL1 may be formed on the adhesive layer AL by an inkjet process. The inkjet apparatus IA may apply the first uncured resin layer RSL1 on the adhesive layer AL. The first uncured resin layer RSL1 may be formed of a urethane acrylate-based resin. In addition, the first uncured resin layer RSL1 may be formed of a resin containing 2-propenoic acid, (5-ethyl-1,3-dioxin-5-yl) methyl ester.

Referring to FIG. 21, the first uncured resin layer RSL1 may be cured to form the buffer CM. The inkjet apparatus IA may radiate ultraviolet light to the first uncured resin layer RSL1 to cure the first uncured resin layer RSL1.

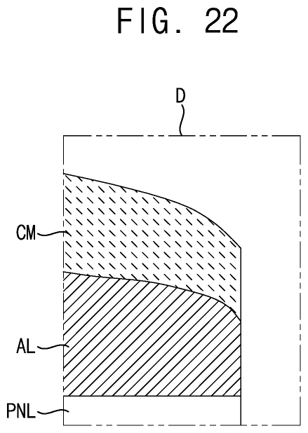

Further referring to FIG. 22, the adhesive layer AL may be formed such that a thickness decreases from the central portion thereof toward the edge at a portion of the edge overlapping the display panel PNL. For example, the adhesive layer AL may be formed by an inkjet process and gradually decrease in thickness toward the edge of adhesive layer AL.

The buffer CM may be formed such that a thickness decreases from the central portion thereof toward the edge at a portion of the edge overlapping the display panel PNL. For example, the buffer CM may be formed by an inkjet process and gradually decrease in thickness toward the edge of the buffer CM.

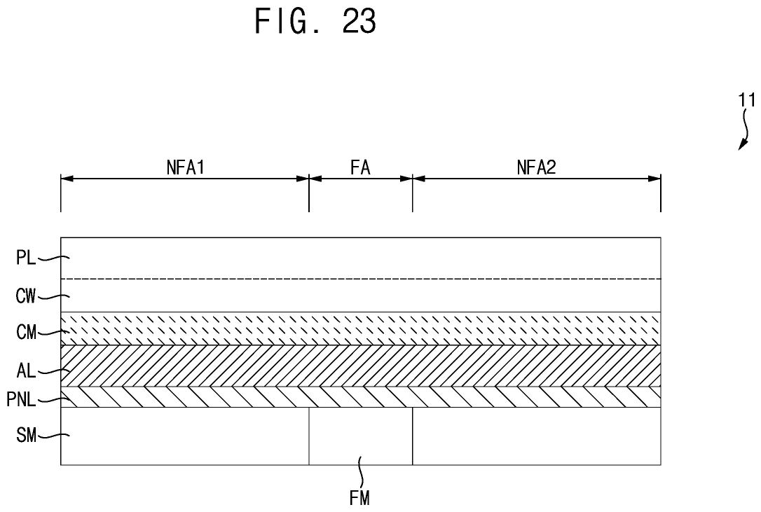

Further referring to FIG. 23, the cover window CW and the protective film PL may be formed on the buffer CM. Also, the support SM may be formed under the display panel PNL. Thus, the display device 11 may be formed.

The invention should not necessarily be construed as being limited to the embodiments set forth herein. Rather, these embodiments are provided so that this disclosure will be thorough and complete and will fully convey the concept of the invention to those skilled in the art.

While example embodiments of the invention has been particularly shown and described with reference to embodiments thereof, it will be understood by those of ordinary skill in the art that various changes in form and details may be made therein without departing from the spirit or scope of present disclosure.

What is claimed is:

1. A display device, comprising:
a display panel including a first non-folding area, a second non-folding area, and a folding area disposed between the first non-folding area and the second non-folding area;
a buffer disposed on the display panel and having a thickness decreasing from a central portion thereof toward an edge thereof overlapping the display panel; and
a cover window disposed on the buffer.

2. The display device of claim 1, wherein the buffer directly contacts the display panel.

3. The display device of claim 1, wherein the buffer includes a curable resin.

4. The display device of claim 1, wherein the buffer includes a urethane acrylate-based resin.

5. The display device of claim 4, wherein the buffer further includes 2-propenoic acid, (5-ethyl-1,3-dioxin-5-yl) methyl ester.

6. The display device of claim 1, wherein a modulus of the buffer is in a range of about 65 Mpa to about 150 Mpa.

7. The display device of claim 1, wherein a thickness of the central portion of the buffer is in a range of about 25 micrometers to about 100 micrometers.

8. The display device of claim 1, wherein the display panel includes:
a circuit element layer including at least one transistor;
a light emitting element layer including at least one light emitting diode and disposed on the circuit element layer; and
an encapsulation layer disposed on the light emitting element layer.

9. The display device of claim 8, wherein the buffer directly contacts the encapsulation layer.

10. The display device of claim 8, wherein the display panel further includes:
a functional layer disposed on the encapsulation layer.

11. The display device of claim 10, wherein the buffer directly contacts the functional layer.

12. The display device of claim 1, further comprising:
an adhesive layer disposed on the buffer, disposed under the cover window, and having a thickness decreasing from a central portion thereof toward an edge thereof overlapping the display panel.

13. The display device of claim 12, wherein the adhesive layer directly contacts each of the buffer and the cover window.

14. The display device of claim 12, wherein the adhesive layer includes a curable resin.

15. The display device of claim 12, wherein a thickness of the central portion of the adhesive layer is in a range of about 35 micrometers to about 100 micrometers.

16. The display device according to claim 12, wherein each of the adhesive layer and the buffer has a viscosity of greater than 0 cP and less than about 50 cP at room temperature.

17. The display device of claim 1, further comprising:
an adhesive layer disposed on the display panel, disposed under the buffer, and having a thickness decreasing from a central portion thereof toward an edge thereof overlapping the display panel.

18. The display device of claim 17, wherein the adhesive layer directly contacts each of the display panel and the buffer.

19. The display device of claim 17, wherein the buffer directly contacts each of the adhesive layer and the cover window.

20. A method of manufacturing a display device, the method comprising:
forming a display panel including a first non-folding area, a second non-folding area, and a folding area disposed between the first non-folding area and the second non-folding area;
forming a buffer having a thickness decreasing from a central portion thereof toward an edge thereof overlapping the display panel, on the display panel; and
forming a cover window on the buffer.

21. The method of claim 20, wherein the buffer is formed through an inkjet process.

22. The method of claim 21, wherein the forming the buffer includes:
forming a first uncured resin layer on the display panel by the inkjet process; and
curing the first uncured resin layer to form the buffer.

23. The method of claim 20, wherein the buffer is formed of a urethane acrylate-based resin.

24. The method of claim 20, wherein the buffer is formed of a resin containing 2-propenoic acid, (5-ethyl-1,3-dioxin-5-yl) methyl ester.

25. The method of claim 20, further comprising:
forming an adhesive layer having a thickness decreasing from a central portion thereof toward an edge thereof overlapping the display panel, on the buffer.

26. The method of claim 25, wherein the adhesive layer is formed by an inkjet process.

27. The method of claim 26, wherein the forming the adhesive layer includes:
forming a second uncured resin layer on the buffer by the inkjet process; and
curing the second uncured resin layer to form the adhesive layer.

28. The method of claim 20, further comprising:
forming an adhesive layer having a thickness decreasing from a central portion thereof toward an edge thereof overlapping the display panel, on the display panel.

29. The method of claim 28, wherein the forming the adhesive layer includes:
forming a second uncured resin layer on the display panel by the inkjet process; and
curing the second uncured resin layer to form the adhesive layer.
